(19) United States
(12) Patent Application Publication
(10) Pub. No.: US 2009/0011150 A1
(43) Pub. Date: Jan. 8, 2009

(54) Remote Plasma Atomic Layer Deposition Apparatus and Method Using Dc Bias

(76) Inventors: Hyeong-Tag Jeon, Seoul (KR); Un-Jung Kim, Seoul (KR); Ju-Youn Kim, Seoul (KR); Jin-Woo Kim, Seoul (KR)

Correspondence Address: LADAS & PARRY LLP, 224 SOUTH MICHIGAN AVENUE, SUITE 1600, CHICAGO, IL, 60604, US

(21) Appl. No.: 11/658,961

(22) PCT Filed: Aug. 4, 2004
(86) PCT No.: PCT/KR2004/001962

§ 371 Date: Jan. 30, 2007

(51) Int. Cl. B01J 19/08; C23C 16/54

(52) U.S. Cl. 427/579; 118/723 ER

(57) ABSTRACT

A conventional plasma applied ALD apparatus has a problem in that physical shock is directly imposed on a substrate and a thin film thereby damaging the thin film. Further, many reports have said that since an apparatus for controlling plasma energy is not arranged well, the thin film is not formed uniformly due to plasma nonuniformity. Therefore, there is provided a remote plasma atomic layer deposition apparatus using a DC bias comprising: a reaction chamber having an inner space; a substrate supporting body on which a substrate on which a thin film is to be formed is loaded arranged at one side of the inner space of the reaction chamber; a remote plasma generating unit arranged outside of the reaction chamber to supply a remote plasma into the inner space of the reaction chamber; a DC bias unit controlling energy of the remote plasma; and a source gas supply unit supplying a source gas for forming the thin film into the reaction chamber.

### TECHNICAL FIELD

The present invention relates to a method and apparatus for forming a thin film, and more specifically, to an atomic layer deposition (ALD) apparatus and method capable of forming a thin film at an atomic level.

### BACKGROUND ART

Thin films are used for various purposes such as a dielectric layer or an active layer of a semiconductor device, a transparent electrode of a liquid crystal display device, and an emission layer and a protective layer of an electroluminescent display device. However, with the development of technology, there is increasing need for a thin film having uniform thickness ranging from several nanometers to several tens of nanometers in an opto-electronic device and a display device, etc.

Typically, the thin film is formed by using a physical deposition method such as sputtering or evaporation, a chemical deposition method such as chemical vapor deposition, and an ALD method etc. In the ALD method, a thin film is formed by decomposing reactants with chemical substitution through a periodic supply of each reactant. The ALD method has benefits of good step coverage, producing a low impurity concentration, low-temperature-process adaptability and accurate controllability for a layer thickness, compared with other conventional deposition methods. Thus, the ALD method is regarded as a key technology in fabricating semiconductor elements for a memory such as a dielectric layer, a diffusion barrier layer and a gate dielectric layer.

In general, a halide-type source gas is widely used in the conventional ALD method. However, the halide-type source has drawbacks in that it erodes an apparatus and a deposition speed is slow. Recently, an ALD method using an organic metal source has been widely used. However, the ALD method using the organic metal source produces a high impurity concentration and a low thin film density.

In order to remove impurities and improve a thin film density, a plasma-applied ALD method in which a surface reaction speed is increased and the surface reaction is performed at a low temperature has been proposed. However, in the associated ALD apparatus, plasma is generated inside a reaction chamber, so that physical shock is directly imposed on the substrate and the thin film and may damage the thin film. Further, according to many reports, it is difficult to use an apparatus for controlling plasma energy, in the plasma-applied ALD method, and thus the thin film may not be uniformly formed due to plasma nonuniformity.

### BRIEF DESCRIPTION OF THE DRAWINGS

FIG. 1 is a schematic diagram of a remote plasma atomic layer deposition apparatus using a DC bias according to an embodiment of the present invention;

FIG. 2 is a schematic cross sectional view of a shower head included in the apparatus of FIG. 1; and

FIG. 3 is a bottom view of the shower head included in the apparatus of FIG. 1.

### DETAILED DESCRIPTION OF THE INVENTION

### Technical Goal of the Invention

The present invention provides a remote plasma ALD (atomic layer deposition) apparatus capable of minimizing thin film damage caused by plasma and forming more uniform thin film.

The present invention also provides a remote plasma ALD method capable of minimizing thin film damage caused by plasma and forming more uniform thin film.

### Disclosure of the Invention

According to an aspect of the present invention, there is provided a remote plasma ALD using a DC bias, comprising: a reaction chamber having an inner space; a substrate supporting body on which a substrate on which a thin film is to be formed is loaded arranged at one side of the inner space of the reaction chamber; a remote plasma generating unit arranged outside of the reaction chamber to supply a remote plasma into the inner space of the reaction chamber; a DC bias unit controlling energy of the remote plasma; and a source gas supply unit supplying a source gas for forming the thin film into the reaction chamber.

According to another aspect of the present invention, there is provided a remote plasma ALD method using a DC bias, comprising: providing a reaction chamber having an inner space; loading a substrate on which a thin film is to be formed inside the reaction chamber; supplying a source gas to the reaction chamber; supplying a carrier gas to the reaction chamber; generating a remote plasma outside the reaction chamber; controlling energy of the remote plasma using the DC bias to capture or accelerate ions or electrons of the plasma; and accelerating radical generation in the source gas using the energy-controlled remote plasma to grow a thin film composed of a single atom layer compound on the substrate.

### EFFECT OF THE INVENTION

In the plasma ALD apparatus according to the present invention, a remote plasma is used, and a flux of activated plasma particles is controlled by a DC bias.

The plasma is generated by a remote plasma generating unit using the DC bias arranged outside the reaction chamber and streams into the reaction chamber, so that it is possible to prevent direct shock to the substrate, unlike in the case where plasma is generated inside the reaction chamber, thereby preventing the substrate and the thin film from being damaged by the plasma.

Further, energy of the remote plasma can be controlled by adjusting the DC bias, so that a single atomic layer constituting an atomic layer thin film can be deposited by supplying appropriate energy to a source gas.

### BEST MODE FOR CARRYING OUT THE INVENTION

The present invention will now be described more fully with reference to the accompanying drawings, in which exemplary embodiments of the invention are shown.

A plasma atomic layer deposition (ALD) apparatus and method according to the present invention are characterized in that a DC bias and a remote plasma are used, and thus, the apparatus and method will be referred to as “remote plasma ALD apparatus and method using DC bias.” The remote plasma ALD apparatus and method using a DC bias according to the present invention will now be described with reference to the accompanying drawings. However, the invention may, however, be embodied in many different forms and should not be construed as being limited to the embodiments set forth herein; rather, these embodiments are provided so that this disclosure will be thorough and complete, and will fully convey the concept of the invention to those skilled in the art.

### EMBODIMENTS

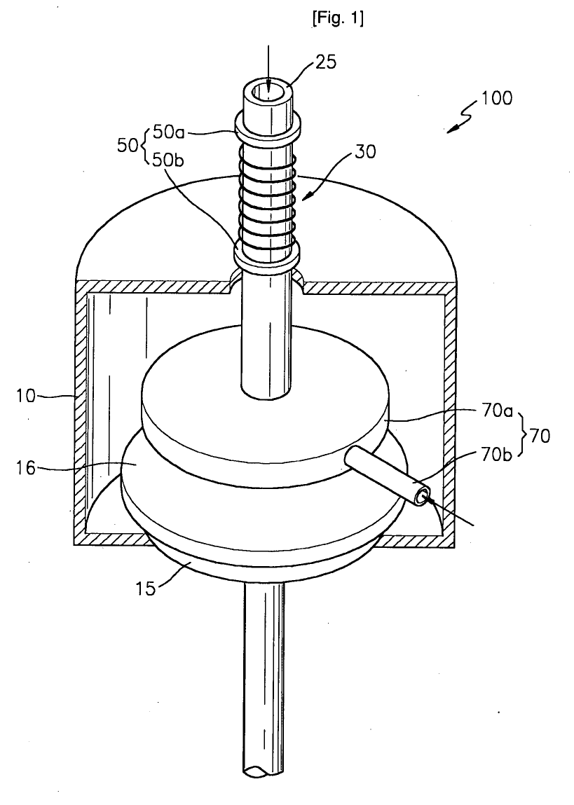

FIG. 1 is a schematic diagram of a remote plasma ALD apparatus 100 using a DC bias according to an embodiment of the present invention.

The remote plasma ALD apparatus 100 comprises an inner reaction chamber 10 for forming a thin film, a remote plasma generating unit 30 for generating plasma, a DC bias unit 50 for controlling the remote plasma, and a source gas supply unit 70.

The inner reaction chamber 10 has an inner space in which a thin film is formed. A substrate supporting body 15 is arranged at one side in the inner space of the inner reaction chamber 10. A substrate 16 on which a thin film is to be formed is loaded onto the substrate supporting body 15. The substrate 16 may be composed of Si, and SiGe, Ge, Al₂O₃, GaAs or SiC.

The source gas supply unit 70 supplies a source gas used to form the thin film into the inner reaction chamber 10. If the thin film to be grown on the substrate 16 is composed of a silicon compound such as silicon oxide, the corresponding source gas is supplied. The source gas supply unit 70 may comprise a shower head 70a and a source gas supply tube 70b connected to one end of the shower head 70a to supply the source gas to the shower head 70a. With the shower head 70a described above, better uniformity of the thin film can be achieved over the entire surface of the substrate 16 compared with a conventional traveling method. The source gas supply unit 70 may be a ring type, a traveling type and another type not mentioned herein. As is well known to those skilled in the art, more than one source gas supply tube 70b may be connected to the shower head 70a, if necessary, to supply more than one type of source gas. In general, the source gas, especially an organic metal source gas, may contain various poisons. Thus, it is desirable that the shower head 70a be composed of nickel, which is invulnerable to the poisons in the source gas, to extend the lifetime of the shower head 70a. The remote plasma ALD apparatus 100 also includes a carrier gas supply unit 25 connected to the inner reaction chamber 10, to supply a carrier gas that carries the source gas into the inner space of the inner reaction chamber 10. Further, the remote plasma generating unit 30 is arranged outside the inner reaction chamber 10 and connected to the carrier gas supply unit 25. The remote plasma generating unit 30 supplies the remote plasma into the inner space of the inner reaction chamber 10. The plasma carries particles activated through an ionization process to the substrate 16 to improve adhesiveness of the thin film material to be deposited and enhance uniformity when growing the thin film.

As shown in FIG. 1, when the source gas supply unit 70 includes the shower head 70a, the shower head type of remote plasma is preferably provided to supply the substrate 16 with the source gas and the remote plasma, which are sprayed from the shower head 70a, via separated paths.

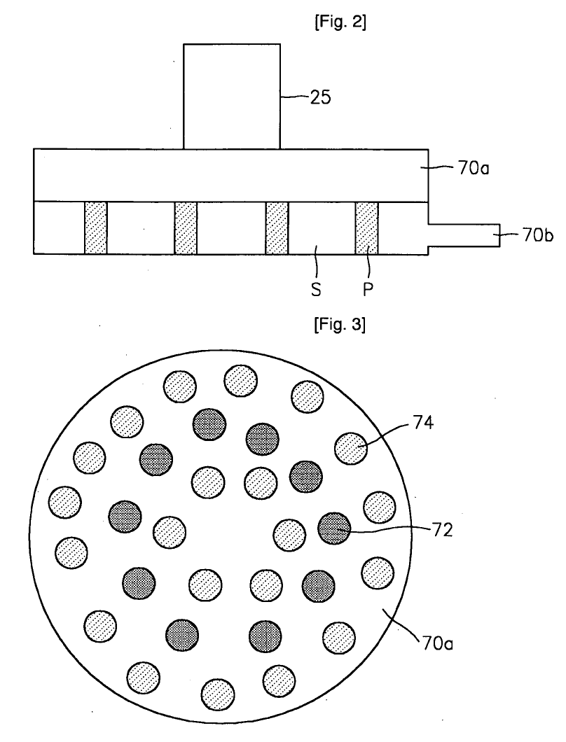

FIG. 2 is a schematic cross sectional view of the shower head 70a. The path S of the source gas and the path P of the remote plasma are separated from each other in the shower head 70a. Spray holes 72 having a predetermined diameter are provided on the bottom of the shower head 70a to spray the source gas supplied through the source gas supply tube 70b into the inner reaction chamber 10. In addition, perforation holes 74 are provided to supply the remote plasma. The shower head 70a is connected to the carrier gas supply unit 25, which supplies the plasma generated by the remote plasma generating unit 30 to the substrate 16 via the path P.

Referring back to FIG. 1, the DC bias unit 50 for controlling energy of the remote plasma is connected to the carrier gas supply unit 25. The DC bias unit 50 comprises two counter electrodes 50a and 50b. When the first electrode 50a is set to a positive voltage, the second electrode 50b is set to a negative voltage, and vice versa. Voltages applied to the counter electrodes 50a and 50b are controlled to adjust the DC bias, thereby controlling the flux of activated plasma particles.

By using the DC bias unit 50 of the apparatus 100, energy of ions and electrons generated in the RF plasma can be controlled so that the intensity of the plasma and the movement of electron in the plasma can be controlled. Therefore, a single atom layer constituting an atomic layer thin film can be deposited by supplying appropriate energy to the source gas. The thin film to be grown on the substrate 16 can be composed of a single crystal, polycrystalline or amorphous compound.

A method of depositing a thin film on the substrate 16 using the remote plasma ALD apparatus 100 will now be described.

The substrate 16 is loaded on the substrate supporting body 15 inside the inner reaction chamber 10, and the source gas is then supplied into the inner reaction chamber 10 via the source gas supply unit 70. Additionally, the carrier gas is supplied to the inner reaction chamber 10 via the carrier gas supply unit 25. The remote plasma is generated in the remote plasma generating unit 30 arranged outside the inner reaction chamber 10, and energy of the remote plasma is controlled using the DC bias produced by the DC bias unit 50, which is further included in the carrier gas supply unit 25. Under this arrangement, ions and electrons in the plasma are captured or accelerated. With the energy controlled remote plasma, a source gas is promoted to generate a radical so that a thin film composed of a single atomic layer compound is grown on the substrate 16.

As described above, the ALD apparatus and method according to the present invention uses remote plasma. The remote plasma, which is generated by the remote plasma generating unit 30 arranged outside the inner reaction chamber 10 and streams into the inner reaction chamber 10 with energy controlled by the DC bias unit 50, does not impose a direct shock on the substrate 16 and the thin film, contrary to the conventional methods in which the plasma is generated inside the inner reaction chamber 10. Therefore, damage to the substrate 16 and the thin film caused by the plasma can be minimized. Further, considering the lifetime of the remote plasma deposited inside the inner reaction chamber 10, the DC bias is applied to an RF plasma so that a remote plasma not affected by a frequency band of the RF plasma, i.e., 13.56 MHz can react with a precursor in the inner reaction chamber 10. As a result, it is possible to stably generate the remote plasma.

An exemplary ALD method with the remote plasma ALD apparatus using the DC bias according to the present invention may include, but is not limited to, a method of periodically supplying a remote H₂, N₂, H₂+N₂, O₂, or NH₃ plasma, an organic metal source, and a metal source to deposit metal, metal oxide or metal nitride on the substrate 16. Accordingly, it is possible to deposit various compounds such as single crystal, amorphous and polycrystalline compounds to form a single atomic layer on a substrate.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

1. A remote plasma atomic layer deposition apparatus using a DC bias comprising:
a reaction chamber having an inner space;
a substrate supporting body on which a substrate on which a thin film is to be formed is loaded arranged at one side of the inner space of the reaction chamber.
a remote plasma generating unit arranged outside of the reaction chamber to supply a remote plasma into the inner space of the reaction chamber;
a DC bias unit controlling energy of the remote plasma; and
a source gas supply unit supplying a source gas for forming the thin film into the reaction chamber.

2. The remote plasma atomic layer deposition apparatus according to claim 1, further comprising: a carrier gas supply unit supplying a carrier gas to carry the source gas into the inner space of the reaction chamber, wherein the remote plasma generating unit is connected to the carrier gas supply unit.

3. The remote plasma atomic layer deposition apparatus according to claim 2, wherein the DC bias unit is included in the carrier gas supply unit.

4. The remote plasma atomic layer deposition apparatus according to claim 1, wherein the remote plasma is supplied to the substrate by a shower-head.

5. The remote plasma atomic layer deposition apparatus according to claim 1, wherein the source gas is supplied to the substrate by a shower-head via a path separate from a path of the remote plasma.

6. The remote plasma atomic layer deposition apparatus according to claim 1, wherein the thin film is composed of oxide.

7. The remote plasma atomic layer deposition apparatus according to claim 1, wherein the thin film is composed of a silicon compound.

8. The remote plasma atomic layer deposition apparatus according to claim 1, wherein the thin film is composed of a single crystal compound.

9. The remote plasma atomic layer deposition apparatus according to claim 1, wherein the thin film is composed of a polycrystalline compound.

10. The remote plasma atomic layer deposition apparatus according to claim 1, wherein the thin film is composed of an amorphous compound.

11. The remote plasma atomic layer deposition apparatus according to claim 1, wherein the substrate is composed of Si.

12. The remote plasma atomic layer deposition apparatus according to claim 1, wherein the substrate is composed of a material selected from the group containing SiGe, Ge, Al₂O₃, GaAs and SiC.

13. A method of depositing a remote plasma atomic layer using a DC bias comprising:
providing a reaction chamber having an inner space;
loading a substrate on which a thin film is to be formed inside the reaction chamber;
supplying a source gas to the reaction chamber;
supplying a carrier gas to the reaction chamber;
generating a remote plasma outside the reaction chamber;
controlling energy of the remote plasma using the DC bias to capture or accelerate ions or electrons of the plasma; and
accelerating radical generation in the source gas using the energy-controlled remote plasma to grow a thin film composed of a single atom layer compound on the substrate.

14. The method according to claim 13, wherein the thin film is composed of a silicon oxide.

15. The method according to claim 13, wherein the thin film is composed of a silicon compound.

16. The method according to claim 13, wherein the thin film is composed of a single crystal compound.

17. The method according to claim 13, wherein the thin film is composed of a polycrystalline compound.

18. The method according to claim 13, wherein the thin film is composed of an amorphous compound.

19. The method according to claim 13, wherein the substrate is composed of Si.

20. The method according to claim 13, wherein the substrate is composed of a material selected from the group containing SiGe, Ge, Al₂O₃, GaAs and SiC.
